(19) United States
(12) Patent Application Publication
(10) Pub. No.: US 2025/0038485 A1
(43) Pub. Date: Jan. 30, 2025

(54) VCSEL-BASED OPTICAL DEVICE HAVING COMMON ANODE AND PLURALITY OF INSULATED CATHODE STRUCTURES, AND OPTICAL MODULE

(71) Applicant: Hana Optronics, Inc., Asan-si (KR)

(72) Inventors: Dong Hyun KIM, Seongnam-si (KR); Hun Joo HAM, Seongnam-si (KR); Yong Gyeong LEE, Hanam-si (KR)

(73) Assignee: Hana Optronics, Inc., Asan-si (KR)

(21) Appl. No.: 18/913,274

(22) Filed: Oct. 11, 2024

Related U.S. Application Data
(63) Continuation of application No. PCT/KR2023/004511, filed on Apr. 4, 2023.

(30) Foreign Application Priority Data
Apr. 15, 2022 (KR) 10-2022-0046610
Dec. 26, 2022 (KR) 10-2022-0184335

(51) Int. Cl. H01S 5/34; H01S 5/042; H01S 5/183; H01S 5/42

(52) U.S. Cl. CPC H01S 5/3416; H01S 5/042; H01S 5/18311; H01S 5/423

(57) ABSTRACT

A VCSEL-based optical device having a common anode and a plurality of insulated cathode structures, and an optical module are disclosed. According to one aspect of the present embodiment, provided are: a VCSEL having a common anode structure so as to have higher optical output at a predetermined voltage; and a VCSEL array.

### CROSS-REFERENCE TO RELATED APPLICATIONS

This application is a continuation of International Application No. PCT/KR2023/004511 filed on Apr. 4, 2023, which claims priority to Korean Patent Application No. 10-2022-0046610, filed on Apr. 15, 2022 and Korean Patent Application No. 10-2022-0184335, filed on Dec. 26, 2022, the entire contents of which are herein incorporated by reference.

### TECHNICAL FIELD

The disclosure relates to an optical device and an optical module based on a VCSEL having a common anode structure and a plurality of cathode structures that is insulated from each other.

### BACKGROUND ART

Contents described in this part merely provide background information of the present embodiment and do not constitute a conventional technology.

In general, a semiconductor laser diode includes an edge emitting laser diode (hereinafter abbreviated as an “EEL”) and a vertical cavity surface emitting laser (hereinafter abbreviated as a “VCSEL”). The EEL lets a laser beam oscillate in a direction parallel to a stack surface of a device because the EEL has a resonant structure in which the EEL forms a direction parallel to the stack surface. The VCSEL lets a laser beam oscillate in a direction perpendicular to a stack surface of a device because the VCSEL has a resonant structure in which the VCSEL has the direction perpendicular to the stack surface.

The VCSEL has advantages in that it can be implemented with low power because the VCSEL has a shorter optical gain length than the EEL and it is advantageous for mass production because the VCSEL can be integrated with high density. Furthermore, the VCSEL can let a laser beam oscillate in a single longitudinal mode and can be tested on a wafer. Moreover, the VCSEL can be easily coupled with an optical fiber and can be implemented as a two-dimensional surface array because the VCSEL can be modulated at a high speed and can let a circular beam oscillate.

The VCSEL has been basically used as a light source within an optical apparatus for optical communication, an optical interconnection, and optical pickup. However, the range of use of the VCSEL is recently expanded up to a light source within an image forming apparatus, such as a LiDAR, face recognition, motion recognition, augmented reality (AR), or virtual reality (VR) apparatus. In particular, the use of the VCSEL in the LiDAR apparatus is increased because the VCSEL has the aforementioned advantages.

In order to improve an output when the VCSEL is used in the LiDAR apparatus, the VCSEL is implemented in the form of an array in which a plurality of VCSELs forms one channel and one or more such channels are disposed.

The LiDAR apparatus needs to output light having strong intensity in order to detect an object up to a long distance and also needs to minimize duration of light in order to protect the eyeball if a person is an object. A light source (VCSEL array) within the LiDAR apparatus needs to output light having a form of a pulse having strong intensity and short duration. To this end, a relatively high operating voltage needs to be applied to the light source within the LiDAR apparatus.

A VCSEL array (light source) within a conventional LiDAR apparatus has been implemented as a common cathode structure in which an n type semiconductor substrate and an n type electrode are disposed at the bottom and a cathode is used in common. An operating voltage is individually applied to VCSELs between channels in the VCSEL array having the common cathode structure. A single driver field effect transistor (FET) is connected to the cathodes of the VCSELs between the channels in common, and the On/Off of the VCSELs are controlled. However, the single driver FET is electrically connected to all of the VCSELs within the VCSEL array as described above. Accordingly, when a pulse of a selected VCSEL is driven, if the driver FET between the pulses of the selected VCSELS is turned off, an inverse voltage attributable to the driver FET is applied to VCSELs to which the operating voltage has not been applied (i.e., unselected). This causes a problem in that the lifespan of the VCSEL is reduced. Furthermore, when the VCSEL of another channel is selected and operated, an added voltage in addition to the existing operating voltage that is commonly applied needs to be applied in order to compensate for a voltage drop attributable to parasitic inductance, which has caused inconvenience that the size of the operating voltage that needs to be applied has to be increased.

### SUMMARY

### Technical Problem

An object of an embodiment of the present disclosure is to provide a VCSEL and a VCSEL array having a greater light output at a given voltage through a common anode structure.

### Technical Solution

According to an aspect of the present embodiment, there is provided a VCSEL, including an n type semiconductor substrate, an n type reflection part formed on the n type semiconductor substrate and having preset reflectivity, one or a plurality of active layers that let light oscillate by recombining holes and electrons, a lower tunneling junction layer disposed between the n type reflection part and the lowest layer, among the active layers, and configured to change a carrier type of a current, a p type reflection part disposed over the n type reflection part and configured to form a pair with the n type reflection part and to induce the light to oscillate, an upper tunneling junction layer disposed between the highest layer, among the active layers, and the p type reflection part and configured to change a carrier type of a current, an oxidation layer disposed between both the reflection parts and configured to improve oscillation efficiency by providing a photon confinement effect and an electron confinement effect, a p type metal layer disposed over the p type reflection part and for an electrical connection so that a current exits from the p type reflection part, and an n type metal layer electrically connected to the n type reflection part so that a current is able to be supplied.

According to an aspect of the present embodiment, the p type reflection part has smaller reflectivity than the n type reflection part.

According to an aspect of the present embodiment, each of the p type reflection part and the n type reflection part includes a distributed Bragg reflector (DBR) structure.

According to an aspect of the present embodiment, the p type reflection part has a smaller number of DBR pairs than the n type reflection part.

According to an aspect of the present embodiment, the active layer is a P-N junction including a multi-quantum well.

According to an aspect of the present embodiment, a tunneling junction layer that changes the carrier type of the current is present between the active layers.

According to an aspect of the present embodiment, there is provided a VCSEL array, including a plurality of VCSEL arrays to which a plurality of VCSEL emitters is connected in parallel. The plurality of VCSEL arrays includes a common n type semiconductor substrate that is shared by all of the arrays, an n type reflection part formed on the n type semiconductor substrate and having preset reflectivity, one or a plurality of active layers that let light oscillate by recombining holes and electrons, a lower tunneling junction layer disposed between the n type reflection part and the lowest layer, among the active layers, and configured to change a carrier type of a current, a p type reflection part disposed over the n type reflection part and configured to form a pair with the n type reflection part and to induce the light to oscillate, an upper tunneling junction layer disposed between the highest layer, among the active layers, and the p type reflection part and configured to change a carrier type of a current, an oxidation layer disposed between both the reflection parts and configured to improve oscillation efficiency by providing a photon confinement effect and an electron confinement effect, a p type metal layer disposed over the p type reflection part and for an electrical connection so that a current exits from the p type reflection part, and an n type metal layer electrically connected to the n type reflection part so that a current is able to be supplied.

According to an aspect of the present embodiment, the p type metal layer is implemented with one or more metal stack layers, among chrome (Cr), titanium (Ti), platinum (Pt), and gold (Au).

According to an aspect of the present embodiment, the n type metal layer is implemented with one or more metal stack layers, among gold (Au), germanium (Ge), or nickel (Ni).

According to an aspect of the present embodiment, each of the upper tunneling junction layer and the lower tunneling junction layer includes a high doping n type layer and a high doping p type layer.

According to an aspect of the present embodiment, there is provided a VCSEL array, including a plurality of VCSEL arrays to which a plurality of VCSEL emitters is connected in parallel and a plurality of driver FET each connected to a cathode of each VCSEL array and configured to determine whether the VCSEL arrays independently operate. The plurality of VCSEL arrays includes a common n type semiconductor substrate that is shared by all of the arrays, an n type reflection part formed on the n type semiconductor substrate and having preset reflectivity, one or a plurality of active layers that let light oscillate by recombining holes and electrons, a lower tunneling junction layer disposed between the n type reflection part and the lowest layer, among the active layers, and configured to change a carrier type of a current, a p type reflection part disposed over the n type reflection part and configured to form a pair with the n type reflection part and to induce the light to oscillate, an upper tunneling junction layer disposed between the highest layer, among the active layers, and the p type reflection part and configured to change a carrier type of a current, an oxidation layer disposed between both the reflection parts and configured to improve oscillation efficiency by providing a photon confinement effect and an electron confinement effect, a p type metal layer disposed over the p type reflection part and for an electrical connection so that a current exits from the p type reflection part, and an n type metal layer electrically connected to the n type reflection part so that a current is able to be supplied.

According to an aspect of the present embodiment, the p type reflection part has smaller reflectivity than the n type reflection part.

According to an aspect of the present embodiment, each of the p type reflection part and the n type reflection part includes a distributed Bragg reflector (DBR) structure.

According to an aspect of the present embodiment, the p type reflection part has a smaller number of DBR pairs than the n type reflection part.

According to an aspect of the present embodiment, the active layer is a P-N junction including a multi-quantum well.

According to an aspect of the present embodiment, a tunneling junction layer that changes the carrier type of the current is present between the active layers.

### Advantageous Effects

As described above, according to an aspect of the present disclosure, there is an advantage in that a greater light output can be achieved at a given voltage through the common anode structure.

### BRIEF DESCRIPTION OF DRAWINGS

FIGS. 1A and 1B are driving circuit diagrams of a VCSEL array according to an embodiment of the present disclosure.

FIG. 2 is a cross-sectional view of a VCSEL according to a first embodiment of the present disclosure.

FIG. 3 is a cross-sectional view of a VCSEL according to a second embodiment of the present disclosure.

FIG. 4 is a cross-sectional view of a VCSEL according to a third embodiment of the present disclosure.

FIG. 5 is a cross-sectional view of a VCSEL according to a fourth embodiment of the present disclosure.

FIG. 6 is a cross-sectional view of VCSELs between different channels of a VCSEL array according to an embodiment of the present disclosure.

FIG. 7 is a cross-sectional view of a portion a-a′ in the VCSEL array according to an embodiment of the present disclosure.

FIG. 8 is a cross-sectional view of a portion b-b′ in the VCSEL array according to an embodiment of the present disclosure.

### DETAILED DESCRIPTION

The present disclosure may be changed in various ways and may have various embodiments. Specific embodiments are to be illustrated in the drawings and specifically described. It should be understood that the present disclosure is not intended to be limited to the specific embodiments, but includes all of changes, equivalents and/or substitutions included in the spirit and technical range of the present disclosure. Similar reference numerals are used for similar components while each drawing is described.

Terms, such as a first, a second, A, and B, may be used to describe various components, but the components should not be restricted by the terms. The terms are used to only distinguish one component from another component. For example, a first component may be referred to as a second component without departing from the scope of rights of the present disclosure. Likewise, a second component may be referred to as a first component. The term “and/or” includes a combination of a plurality of related and described items or any one of a plurality of related and described items.

When it is described that one component is “connected” or “coupled” to the other component, it should be understood that one component may be directly connected or coupled to the other component, but a third component may exist between the two components. In contrast, when it is described that one component is “directly connected” or “directly coupled” to the other component, it should be understood that a third component does not exist between the two components.

Terms used in this application are used to only describe specific embodiments and are not intended to restrict the present disclosure. An expression of the singular number includes an expression of the plural number unless clearly defined otherwise in the context. In this specification, a term, such as “include” or “have”, is intended to designate the presence of a characteristic, a number, a step, an operation, a component, a part or a combination of them, and should be understood that it does not exclude the possible existence or addition of one or more other characteristics, numbers, steps, operations, components, parts, or combinations of them in advance.

All terms used herein, including technical terms or scientific terms, have the same meanings as those commonly understood by a person having ordinary knowledge in the art to which the present disclosure pertains, unless defined otherwise in the specification.

Terms, such as those defined in commonly used dictionaries, should be construed as having the same meanings as those in the context of a related technology, and are not construed as ideal or excessively formal meanings unless explicitly defined otherwise in the application.

Furthermore, each construction, process, procedure, or method included in each embodiment of the present disclosure may be shared within a range in which the constructions, processes, procedures, or methods do not contradict each other technically.

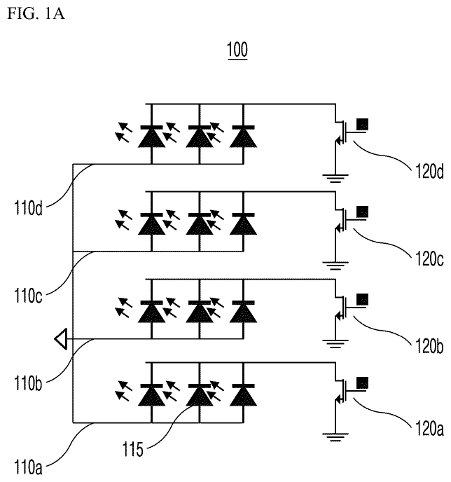

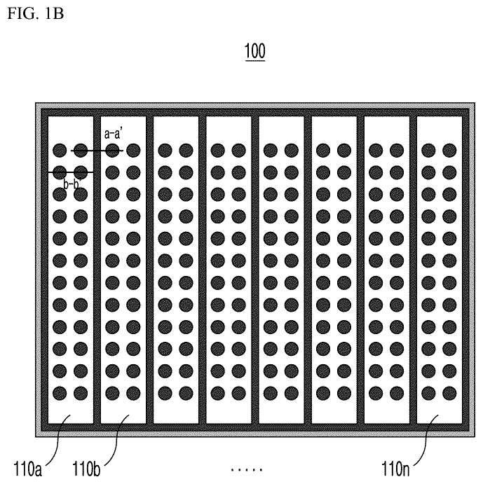

FIGS. 1A and 1B are driving circuit diagrams of a VCSEL array according to an embodiment of the present disclosure.

Referring to FIGS. 1A and 1B, a VCSEL array 100 according to an embodiment of the present disclosure includes one or more VCSEL channels 110 and a driver FET 120.

The VCSEL array 100 includes the one or more VCSEL channels 110. Each VCSEL channel 110 has one end applied with an operating voltage VH and the other end connected to the driver FET 120, and whether each VCSEL channel will operate is controlled. In this case, one end of each VCSEL channel 110 and one end of each VCSEL channel 10 are connected in common, and the same operating voltage is applied to all of the VCSEL channels 110. Whether a specific VCSEL channel 110 will operate is determined based on whether the driver FET 120 connected to the other end of each VCSEL channel 110 is turned on or off.

The VCSEL channel 110 includes a plurality of VCSELs 115 that is connected in parallel. In this case, the anode of each VCSEL 115 is disposed toward one end of the channel, and the cathode of each VCSEL 115 is disposed toward the driver FET 120. Accordingly, the anodes of all of the VCSELs within the VCSEL array 100 are characterized as being common.

As the anodes of VCSELs within each channel are common and a different driver FET 120 is connected to each channel, the following effects occur. Although a first channel is selected and driven and a driver FET is turned off (between pulses) as in a conventional technology, a second channel is not subjected to an influence attributable to the driver FET of the first channel because one driver FET is not connected to all of channels, but a different driver FET 120 is connected to each channel. Accordingly, an unnecessary reduction in the lifespan of VCSELs within a channel that does not operate can be prevented because a continued inverse voltage is not applied to channels that do not operate.

Furthermore, parasitic inductance that essentially occurs does not affect different channels because a different driver FET is connected to each channel.

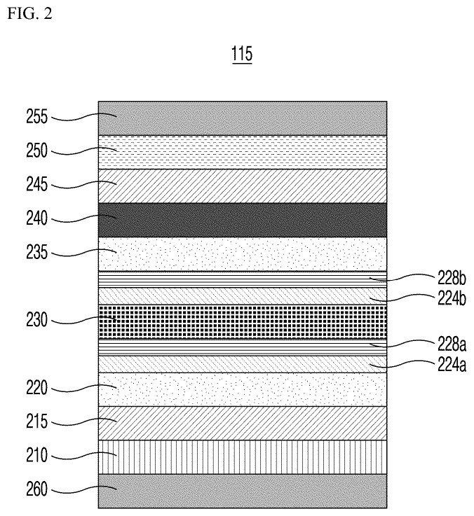

Each VCSEL 115 has structures illustrated in FIGS. 2 to 5 so that the VCSEL array 100 or each channel 110 within the VCSEL array can have a common anode structure.

FIG. 2 is a cross-sectional view of a VCSEL according to a first embodiment of the present disclosure.

Referring to FIG. 2, the VCSEL 115 according to the first embodiment of the present disclosure includes an n type semiconductor substrate 210, an n type reflection layer 215, an n type layer 220, a lower tunneling junction layer 224a and 228a, a upper tunneling junction layer 224b and 228b, an active layer 230, a p type layer 235, an oxidation layer 240, a p type reflection layer 245, a p type contact layer 250, a p type metal layer 255, and an n type metal layer 260.

In the VCSEL 115 that enables the VCSEL array 100 or each channel 110 within the VCSEL array to have the common anode structure, as will be described later, each layer is grown on the n type semiconductor substrate 210. A p type semiconductor substrate cannot be relatively much doped compared to the n type semiconductor substrate 210. Although the p type semiconductor substrate is much doped, resistance is significantly increased because the carrier mobility is reduced. Accordingly, the VCSEL including the p type semiconductor substrate, which enables the VCSEL array or each channel within the VCSEL array to have the common anode structure, is subjected to a great voltage drop and also generates a relatively large amount of heat because the VCSEL has relatively high resistance. In contrast, the VCSEL 115 including the n type semiconductor substrate 210 can solve the aforementioned problems.

The n type semiconductor substrate 210 supports each component of the VCSEL 115. The n type semiconductor substrate 210 has a characteristic in that it has relatively excellent electrical conductivity compared to the p type substrate. The n type semiconductor substrate 210 may have a flexible characteristic or an inflexible characteristic (i.e., rigid).

The n type reflection layer 215 may be made of a semiconductor material doped with an n type dopant, and may be made of AlGaAs, that is, a semiconductor material including Al. The n type reflection layer 215 consists of a plurality of distributed Bragg reflector (DBRs) pairs. The plurality of DBR pairs in each of which a high Al composition layer including a high aluminum (Al) ratio of 80 to 95% and a low Al composition layer including a low Al ratio of 5 to 20% form one pair is implemented. The n type reflection layer 215 includes a larger number of DBR pairs and relatively higher reflectivity than the p type reflection layer 245. Accordingly, light or a laser that oscillates in the active layer 230 oscillates toward the p type reflection layer 245 having low reflectivity because the p type reflection layer has a relatively small number of pairs.

The n type layer 220 is grown on the n type reflection layer 215, and adjusts the optical phase of the VCSEL 115.

The lower tunneling junction layer 224a and 228a is grown on the n type layer 220, more specifically, between the n type reflection layer 215 and the lowest layer to be described later, among the active layers. The lower tunneling junction layer 224a and 228a converts the carrier type of a current so that the tunneling phenomenon of electrons can occur and also enables layers having a p type to be grown on the n type layer 220. The lower tunneling junction layer 224a and 228a includes a high doping n type layer 224a and a high doping p type layer 228a. The layers 224a and 228a may be implemented with an n++ layer and a p++ layer, respectively, for example. The n type layer or the p type layer composed of all or some of InGaAs, InGaP, InP, GaAs, AlGaAs, AlGaAsP, and GaAsP is doped with impurities of 1*10¹⁹/cm³ or more.

The active layer 230 is a layer in which holes generated by the n type reflection layer 215 and electrons generated by the p type reflection layer 245 meet each other and are recombined. Light is generated by the recombination of electrons and holes. The active layer 230 may be implemented with a multi-quantum well (MQW), and has a structure in which well layers (not illustrated) having different energy bands and a barrier layer (not illustrated) are alternately stacked once or more. The well layer (not illustrated)/barrier layer (not illustrated) of the active layer 230 may be made of InGaAs/AlGaAs, InGaAs/GaAs, InGaAs/GaAsP, InGaAs/AlGaAsP, etc.

The upper tunneling junction layer 224b and 228b is grown on the active layer 230, more specifically, between the highest layer, among the active layers 230, and the p type reflection layer 245 to be described later, for the same reason as that of the lower tunneling junction layer 224a and 228a. Likewise, the upper tunneling junction layer 224b and 228b includes a high doping n type layer 224b and a high doping p type layer 228b.

The upper tunneling junction layer 224b and 228b is disposed to neighbor the active layer 230 or disposed within 50 to 200 nm on the basis of the active layer 230. In particular, the upper tunneling junction layer 224b and 228b may be disposed at a point of N/4 and 32/4, that is, the node position of the optical field of the active layer 230. Furthermore, the upper tunneling junction layer 224b and 228b is grown to have a larger number than the number of active layers 230 by one, in order to enable the active layer 230 to be grown on the n type semiconductor substrate 210, to enable the metal layer 260 that is grown on the n type semiconductor substrate 210 to play a role as an anode, and also to enable the p type reflection layers 245, 250, and 255 to be grown.

The p type layer 235 is grown on the high doping p type layer 228b, and adjusts the optical phase of the VCSEL 115.

The thickness of the n type layer 220 or the p type layer 235 may be adjusted as follows. The thickness of the n type layer 220 or the p type layer 235 may be adjusted so that a length between the reflection layers 215 and 245 is longer than a length between the reflection layers when the lower tunneling junction layer and the upper tunneling junction layer are not present, by an integer multiple of a wavelength 2. The thickness of the n type layer 220 may be adjusted, for convenience sake, but the present disclosure is not essentially limited thereto and the thickness of the p type layer 235 may be adjusted. If the thickness is adjusted as described above, resonance may occur in light that is reflected by each reflection layer.

As the oxidation layer 240 experiences an oxidation process, an oxidized portion having a predetermined length is formed. The characteristics of a laser that is output and the diameter of an opening are determined based on the length of the oxidized portion. The oxidation layer 240 may be made of aluminum (Al) having a higher concentration (e.g., 95% or more) than each of the n type reflection layer 215 and the p type reflection layer 245. As the concentration of Al is higher, the speed at which the oxidation layer is oxidized is increased. As the oxidation layer 240 has a relatively higher concentration of Al than each of the reflection layers 215 and 245, oxidation can be selectively performed when the oxidation is subsequently performed. For example, the oxidation layer 240 may be implemented with AlGaAs having an Al ratio of 95% or more. Each of the reflection layers 215 and 245 may be implemented with AlGaAs having an Al ratio of 5% to 95%.

Furthermore, the oxidation layer 240 improves oscillation efficiency by providing a photon confinement effect and an electron confinement effect.

The oxidation layer 240 is formed to be adjacent to any one of the high doping n type layer 224 and the high doping p type layer 228. An n type layer or a p type layer may be disposed between the two (224/228 and 240) in order to adjust the optical phase.

The p type reflection layer 245 may be made of a semiconductor material doped with a p type dopant, and may be made of AlGaAs, that is, a semiconductor material including Al. Likewise, the p type reflection layer 245 consists of a plurality of DBR pairs. As described above, the p type reflection layer 245 has relatively low reflectivity because the p type reflection layer has a relatively smaller number of DBR pairs than the n type reflection layer 215. Accordingly, light or a laser that oscillates in the active layer 230 oscillates toward the p type reflection layer 245.

The p type contact layer 250 is grown on the p type reflection layer 245, and connects the p type reflection layer 245 and the p type metal layer 255.

The p type metal layer 255 is connected to an electrode (−) as a cathode, and enables the VCSEL 115 to be supplied with electrons from the outside. The p type metal layer 255 enables a current to exit from the p type reflection layer 245. The p type metal layer 255 may be implemented with any one metal stack layer, among chrome (Cr), titanium (Ti), platinum (Pt), and gold (Au).

The n type metal layer 260 is grown at the bottom (a direction opposite to a direction in which the n type reflection layer is grown) of the n type semiconductor substrate 210 and connected to an electrode (+) as an anode, and enables the VCSEL 115 to be supplied with holes from the outside. The n type metal layer 260 may be implemented with one or more metal stack layers, among gold (Au), germanium (Ge), and nickel (Ni).

As described above, although each layer is grown on the n type semiconductor substrate 210, the n type semiconductor substrate can also operate as the anode because the high doping layers 224 and 228 are grown on the n type semiconductor substrate 210.

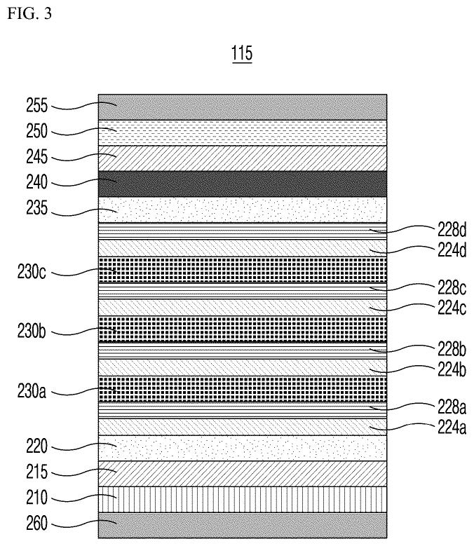

FIG. 3 is a cross-sectional view of a VCSEL according to a second embodiment of the present disclosure.

Referring to FIG. 3, the VCSEL 115 according to the second embodiment of the present disclosure includes all of the components within the VCSEL 115 according to the first embodiment of the present disclosure, but includes a plurality of active layers 230a to 230c and high doping n type layers 224a to 224d/high doping p type layers 228a to 228d having a larger number than active layers by one.

As the plurality of active layer is included within the VCSEL 115, the VCSEL 115 has an advantage in that it can improve the intensity of light to be output.

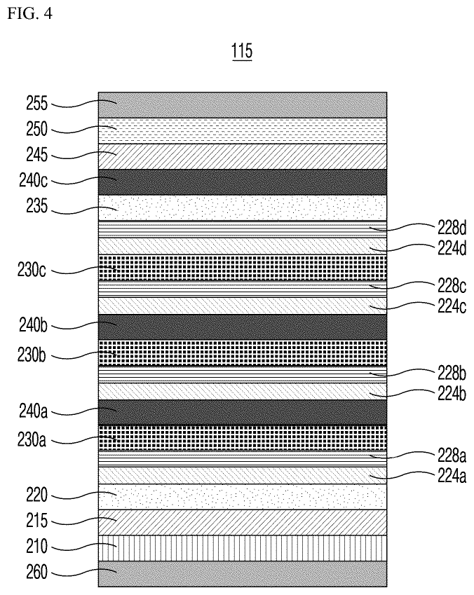

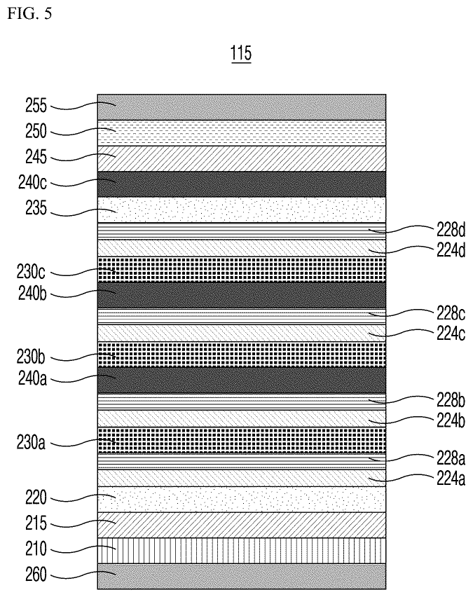

FIG. 4 is a cross-sectional view of a VCSEL according to a third embodiment of the present disclosure. FIG. 5 is a cross-sectional view of a VCSEL according to a fourth embodiment of the present disclosure.

Referring to FIGS. 4 and 5, the VCSEL 115 according to the third and fourth embodiments of the present disclosure includes all of the components within the VCSEL 115 according to the second embodiment of the present disclosure, but further includes a plurality of oxidation layers 240b and 240c.

The oxidation layers 240b and 240c may be disposed between the active layer 230 and the high doping n type layer 224 as in the VCSEL 115 according to the third embodiment of the present disclosure, and may be disposed between the high doping p type layer 228 and the active layer 230 as in the VCSEL 115 according to the fourth embodiment of the present disclosure.

As the VCSEL 115 additionally further includes the active layer 230, the characteristics of a laser to be output and the diameter of an opening can be adjusted more finely.

Although not illustrated in FIGS. 4 and 5, an n type layer or a p type layer may be additionally disposed between the active layer 230 and the high doping layers 224 and 228 in order to adjust the optical phase.

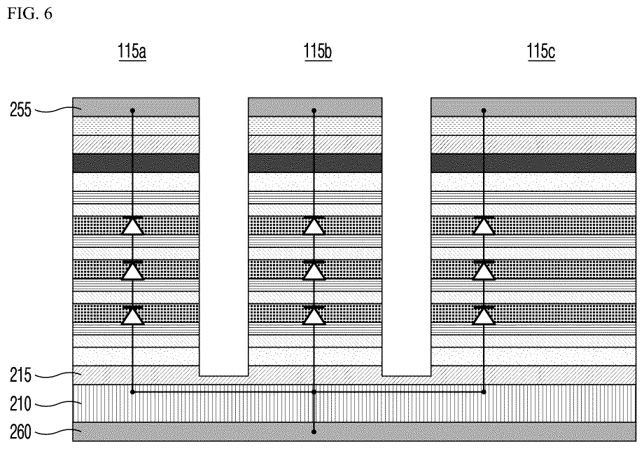

FIG. 6 is a cross-sectional view of VCSELs between different channels of a VCSEL array according to an embodiment of the present disclosure.

The VCSELs 115 between different channels 110 of the VCSEL array have a common anode structure in which the VCSELs have at least the substrate 210 and the n type metal layer 260 grown at the bottom of the substrate in common. As described above, although the VCSEL 115 is implemented according to any embodiment of the first to fourth embodiments, the n type metal layer 260 grown at the bottom of the substrate operates as the anode (+). Accordingly, adjacent VCSELs 115 within one channel 110 have a common anode structure in which the VCSELs have at least the substrate 210 and the n type metal layer 260 in common. The metal layer 255 on the opposite side, which operates as a cathode (−), is connected to each driver FET 120.

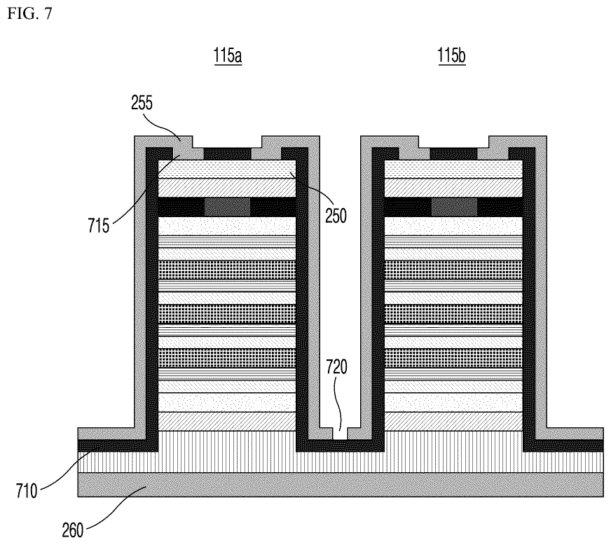

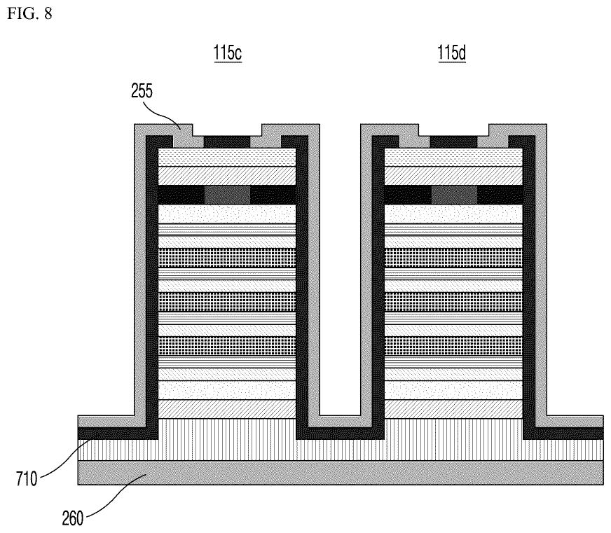

FIG. 7 is a cross-sectional view of a portion a-a′ in the VCSEL array according to an embodiment of the present disclosure. FIG. 8 is a cross-sectional view of a portion b-b′ in the VCSEL array according to an embodiment of the present disclosure.

Referring to FIGS. 7 and 8, an insulating layer 710, for example, silicon dioxide (SiO₂) or silicon nitride (Si₃N₄) is applied in the outskirts of the VCSEL 115. As the insulating layer 710 is applied, each component of the VCSEL 115 can be protected against an external environment because each component of the VCSEL 115 is prevented from being exposed to the outside.

Etching is performed on one portion 715 of the insulating layer 710 on the p type contact layer 250. Thereafter, the p type metal layer 255 is grown on the insulating layer 710. The p type contact layer 250 and the p type metal layer 255 are electrically connected through the etched portion 715.

As illustrated in FIG. 7, as the p type metal layers 255 of VCSELs between different channels are not connected, different driver FETs may be connected to the channels.

As illustrated in FIG. 8, as the p type metal layers 255 of the VCSELs of the same channel are connected, one driver FET may be connected to all of the VCSELs within each channel.

The above description is merely a description of the technical spirit of the present embodiment, and those skilled in the art may change and modify the present embodiment in various ways without departing from the essential characteristic of the present embodiment. Accordingly, the embodiments should not be construed as limiting the technical spirit of the present embodiment, but should be construed as describing the technical spirit of the present embodiment. The technical spirit of the present embodiment is not restricted by the embodiments. The range of protection of the present embodiment should be construed based on the following claims, and all of technical spirits within an equivalent range of the present embodiment should be construed as being included in the scope of rights of the present embodiment.

1. A vertical cavity surface emitting laser (VCSEL) comprising:
an n type semiconductor substrate;
an n type reflection part formed on the n type semiconductor substrate and having preset reflectivity;
one or a plurality of active layers configured to let light oscillate by recombining holes and electrons;
a lower tunneling junction layer disposed between the n type reflection part and a lowest layer, among the active layers, and configured to change a carrier type of a current;
a p type reflection part disposed over the n type reflection part and configured to form a pair with the n type reflection part and to induce the light to oscillate;
an upper tunneling junction layer disposed between a highest layer, among the active layers, and the p type reflection part and configured to change a carrier type of a current;
an oxidation layer disposed between both the reflection parts and configured to improve oscillation efficiency by providing a photon confinement effect and an electron confinement effect;
a p type metal layer disposed over the p type reflection part and for an electrical connection so that a current exits from the p type reflection part; and
an n type metal layer electrically connected to the n type reflection part so that a current is able to be supplied.

2. The VCSEL of claim 1, wherein the p type reflection part has smaller reflectivity than the n type reflection part.

3. The VCSEL of claim 2, wherein each of the p type reflection part and the n type reflection part comprises a distributed Bragg reflector (DBR) structure.

4. The VCSEL of claim 3, wherein the p type reflection part has a smaller number of DBR pairs than the n type reflection part.

5. The VCSEL of claim 1, wherein the active layer is a P-N junction comprising a multi-quantum well.

6. The VCSEL of claim 1, wherein a tunneling junction layer that changes the carrier type of the current is present between the active layers.

7. A VCSEL array comprising:
a plurality of VCSEL arrays to which a plurality of VCSEL emitters is connected in parallel,
wherein the plurality of VCSEL arrays comprises:
a common n type semiconductor substrate that is shared by all of the arrays;
an n type reflection part formed on the n type semiconductor substrate and having preset reflectivity;
one or a plurality of active layers configured to let light oscillate by recombining holes and electrons;
a lower tunneling junction layer disposed between the n type reflection part and a lowest layer, among the active layers, and configured to change a carrier type of a current;
a p type reflection part disposed over the n type reflection part and configured to form a pair with the n type reflection part and to induce the light to oscillate;
an upper tunneling junction layer disposed between a highest layer, among the active layers, and the p type reflection part and configured to change a carrier type of a current;
an oxidation layer disposed between both the reflection parts and configured to improve oscillation efficiency by providing a photon confinement effect and an electron confinement effect;
a p type metal layer disposed over the p type reflection part and for an electrical connection so that a current exits from the p type reflection part; and
an n type metal layer electrically connected to the n type reflection part so that a current is able to be supplied.

8. The VCSEL array of claim 7, wherein the p type metal layer is implemented with one or more metal stack layers, among chrome (Cr), titanium (Ti), platinum (Pt), and gold (Au).

9. The VCSEL array of claim 7, wherein the n type metal layer is implemented with one or more metal stack layers, among gold (Au), germanium (Ge), or nickel (Ni).

10. The VCSEL array of claim 7, wherein each of the upper tunneling junction layer and the lower tunneling junction layer comprises a high doping n type layer and a high doping p type layer.

11. A VCSEL array comprising:
a plurality of VCSEL arrays to which a plurality of VCSEL emitters is connected in parallel; and
a plurality of driver FETs each connected to a cathode of each VCSEL array and configured to determine whether the VCSEL arrays independently operate,
wherein the plurality of VCSEL arrays comprises:
a common n type semiconductor substrate that is shared by all of the arrays;
an n type reflection part formed on the n type semiconductor substrate and having preset reflectivity;
one or a plurality of active layers configured to let light oscillate by recombining holes and electrons;
a lower tunneling junction layer disposed between the n type reflection part and a lowest layer, among the active layers, and configured to change a carrier type of a current;
a p type reflection part disposed over the n type reflection part and configured to form a pair with the n type reflection part and to induce the light to oscillate;
an upper tunneling junction layer disposed between a highest layer, among the active layers, and the p type reflection part and configured to change a carrier type of a current;
an oxidation layer disposed between both the reflection parts and configured to improve oscillation efficiency by providing a photon confinement effect and an electron confinement effect;
a p type metal layer disposed over the p type reflection part and for an electrical connection so that a current exits from the p type reflection part; and
an n type metal layer electrically connected to the n type reflection part so that a current is able to be supplied.

12. The VCSEL array of claim 11, wherein the p type reflection part has smaller reflectivity than the n type reflection part.

13. The VCSEL array of claim 12, wherein each of the p type reflection part and the n type reflection part comprises a distributed Bragg reflector (DBR) structure.

14. The VCSEL array of claim 13, wherein the p type reflection part has a smaller number of DBR pairs than the n type reflection part.

15. The VCSEL array of claim 11, wherein the active layer is a P-N junction comprising a multi-quantum well.

16. The VCSEL array of claim 11, wherein a tunneling junction layer that changes the carrier type of the current is present between the active layers.
